(19) United States
(12) Patent Application Publication
(10) Pub. No.: US 2023/0298950 A1
(43) Pub. Date: Sep. 21, 2023

(54) BOND WIRE LOSS DETECTION AND REDUNDANCY

(71) Applicant: SEMICONDUCTOR COMPONENTS INDUSTRIES, LLC, Phoenix, AZ (US)

(72) Inventor: Dieter Jozef JOOS, Nieuwenrode (BE)

(73) Assignee: SEMICONDUCTOR COMPONENTS INDUSTRIES, LLC, Phoenix, AZ (US)

(21) Appl. No.: 17/654,847

(22) Filed: Mar. 15, 2022

(51) Int. Cl. H01L 21/66; H01L 23/00; G01R 31/28; G01R 25/00

(52) U.S. Cl. CPC H01L 22/30; H01L 24/48; G01R 31/2884; G01R 25/00; H01L 2224/4823; H03K 3/356

(57) ABSTRACT

In some aspects, the techniques described herein relate to a semiconductor device including: a package including a plurality of pins; a semiconductor die including: a first bond pad; a second bond pad; and a pass transistor having: a drain terminal electrically coupled with the first bond pad; and a source terminal electrically coupled with the second bond pad; a first bond wire extending between a pin of the plurality of pins and the first bond pad; and a second bond wire extending between the pin and the second bond pad, the pass transistor being configured to facilitate detection of at least one of: lack of electrical continuity between the pin and the first bond pad; or lack of electrical continuity between the pin and the second bond pad.

### TECHNICAL FIELD

This description relates to semiconductor devices and, more particularly, to detection of bond wire loss in semiconductor devices and associated redundancy mechanisms.

### BACKGROUND

Semiconductor devices, such as integrated circuit devices (ICs), can be susceptible to various failure mechanisms. For instance, bond wire loss, or bond wire failure is a predominant failure mechanism for ICs that are included in a package with bond wires connecting pins (e.g., signal pins, power supply pins, etc.) with bond pads included on a corresponding IC. In some applications, such as automotive applications, devices and systems that implement and/or affect safety functions of a vehicle can be required to meet functional safety standard requirements, where those requirements can vary based on an assigned risk level. For instance, in automotive systems, automotive safety integrity level standards (ASILs) may apply that, based on risk level, require a percentage of all potential faults, which can be referred to as single point failure metrics (SPFMs), to be covered by a safety a mechanism (e.g., a detection mechanism and/or redundancy mechanism), or shown to not impact safe operation of an associated system. These percentages can be, for example, ninety percent for medium risk functions (e.g., light sensor, rain sensor), ninety-seven percent for high risk functions (e.g., unable to deploy air bag, loss of anti-lock braking), and ninety-nine percent for extremely high risk functions (e.g., prevention of unwanted air bag deployment, loss of braking).

### SUMMARY

In some aspects, the techniques described herein relate to a semiconductor device including: a package including a plurality of pins; a semiconductor die including: a first bond pad; a second bond pad; and a pass transistor having: a drain terminal electrically coupled with the first bond pad; and a source terminal electrically coupled with the second bond pad; a first bond wire extending between a pin of the plurality of pins and the first bond pad; and a second bond wire extending between the pin and the second bond pad, the pass transistor being configured to facilitate detection of at least one of: lack of electrical continuity between the pin and the first bond pad; or lack of electrical continuity between the pin and the second bond pad.

In some aspects, the techniques described herein relate to a semiconductor device, wherein: detecting the lack of electrical continuity between the pin and the first bond pad includes detecting a positive voltage shift between the first bond pad and the second bond pad; and detecting the lack of electrical continuity between the pin and the second bond pad includes detecting a negative voltage shift between the first bond pad and the second bond pad.

In some aspects, the techniques described herein relate to a semiconductor device, wherein the semiconductor die further includes a bond wire loss detection circuit operationally coupled with the first bond pad and operationally coupled with the second bond pad, the bond wire loss detection circuit being configured to detect a voltage differential between the first bond pad and the second bond pad.

In some aspects, the techniques described herein relate to a semiconductor device, wherein: the bond wire loss detection circuit is further operationally coupled with a gate terminal of the pass transistor; and the bond wire loss detection circuit is further configured, in response to the detected voltage differential exceeding a threshold, to activate the pass transistor, such that the pass transistor provides a conductive path between the first bond pad and the second bond pad.

In some aspects, the techniques described herein relate to a semiconductor device, wherein the semiconductor die further includes a latch operationally coupled between the bond wire loss detection circuit and a gate terminal of the pass transistor, the bond wire loss detection circuit being further configured, in response to the detected voltage differential exceeding a threshold, to set the latch, and the latch being configured, when set, to activate the pass transistor, such that the pass transistor provides a conductive path between the first bond pad and the second bond pad.

In some aspects, the techniques described herein relate to a semiconductor device, wherein: the latch is a set-reset latch, the set-reset latch being configured, when reset, to deactivate the pass transistor.

In some aspects, the techniques described herein relate to a semiconductor device, further including at least one functional block configured to release a reset signal of the set-reset latch in response to a supply voltage of the semiconductor device increasing from below a supply voltage threshold to above the supply voltage threshold.

In some aspects, the techniques described herein relate to a semiconductor device, wherein an output signal of the latch is accessible external to the semiconductor device.

In some aspects, the techniques described herein relate to a semiconductor device, wherein the pass transistor is an n-channel metal-oxide-semiconductor (NMOS) transistor.

In some aspects, the techniques described herein relate to a semiconductor device, wherein the NMOS transistor is a native NMOS transistor.

In some aspects, the techniques described herein relate to a semiconductor device, wherein the pin is an electrical ground supply pin of the semiconductor device.

In some aspects, the techniques described herein relate to an integrated circuit including: a first bond pad coupled with a ground supply bus for the integrated circuit; a pass transistor having a drain terminal, a source terminal and a gate terminal, the drain terminal being electrically coupled with the first bond pad; a second bond pad electrically coupled with the source terminal; a detection circuit operationally coupled with the first bond pad and the second bond pad, the detection circuit being configured to: detect a voltage differential between a voltage on the first bond pad and a voltage on the second bond pad; and if the voltage differential exceeds a threshold, provide an indication signal; and a set-reset latch configured to set an output signal in response to receiving the indication signal, the gate terminal being configured to; receive the output signal; and activate the pass transistor in response to the output signal being set, such that the pass transistor provides a conductive path between the first bond pad and the second bond pad.

In some aspects, the techniques described herein relate to an integrated circuit, further including at least one functional block configured to release a reset signal of the set-reset latch in response to a supply voltage of the semiconductor device increasing from below a supply voltage threshold to above the supply voltage threshold.

In some aspects, the techniques described herein relate to an integrated circuit, wherein an output signal of the set-reset latch is accessible external to the integrated circuit.

In some aspects, the techniques described herein relate to an integrated circuit, wherein the pass transistor is an n-channel metal-oxide-semiconductor (NMOS) transistor.

In some aspects, the techniques described herein relate to an integrated circuit including: a first bond pad electrically coupled with a ground supply bus for the integrated circuit; a pass transistor having a drain terminal, a source terminal and a gate terminal, the drain terminal being electrically coupled with the first bond pad; a second bond pad electrically coupled with the source terminal; and a bias circuit operationally coupled with the gate terminal, the bias circuit being configured to: in a normal operation mode of the integrated circuit, activate the pass transistor; and in a test mode of the integrated, deactivate the pass transistor.

In some aspects, the techniques described herein relate to an integrated circuit, wherein the pass transistor is an n-channel metal-oxide-semiconductor (NMOS) transistor.

In some aspects, the techniques described herein relate to an integrated circuit, wherein the NMOS transistor is a native NMOS transistor.

In some aspects, the techniques described herein relate to an integrated circuit, wherein deactivating the pass transistor includes applying a negative voltage to the gate terminal.

### BRIEF DESCRIPTION OF THE DRAWINGS

FIG. 1 is a block/schematic diagram illustrating a semiconductor device that implements bond wire loss detection.

FIG. 2 is a block diagram illustrating another semiconductor device that implements bond wire loss detection.

FIG. 3 is a is a block/schematic diagram illustrating another semiconductor device that implements bond wire loss detection.

FIG. 4 is a block/schematic diagram illustrating a bond wire loss feedback circuit that implements bond wire loss detection.

Like reference symbols in the various drawings indicate like and/or similar elements.

### DETAILED DESCRIPTION

In order to best comply with safety standard requirements for packaged ICs, manufacturers may target to have one-hundred percent coverage (e.g., implement a detection and/or safety mechanism) for all potential single point faults. In some implementations, this objective can be difficult to achieve. For instance, with reference to the example of bond wire loss noted above, in a packaged IC with a limited number of pins (e.g., sixteen pins) the loss of a single bond wire connection that is not covered (e.g., detectable and/or covered by a safety mechanism) would result in failure to meet the high risk and extremely high risk ASIL requirements discussed above. That is, for a device with sixteen pins that are safety related, compliance with the functional safety standard (having fault coverage) for only fifteen of the sixteen pins would result in approximately ninety-three percent coverage for bond wire loss single-point faults, which will negatively influence the overall SPFMs(single point failure metrics), since ninety-three percent for package fault coverage is below the ninety-seven and ninety-nine percent requirements for high risk and extremely high risk safety functions.

Current approaches to reduce the probability of a functional fault due to bond wire loss may not achieve compliance with functional safety standards. For instance, use of multiple parallel connected bond wires to connect a package pin with a corresponding bond pad on an IC can reduce the probability of a resultant functional failure of the IC (e.g., due to loss of all bond wires). However, in the case of multiple parallel connected bond wires, detection of the failure of a single bond wire cannot be accurately detected during testing of the associated device (e.g., due to variation of bond wire resistance in combination with test equipment accuracy). Accordingly, such a single point fault (loss of a single bond wire) would be considered to not be covered during production testing and, as such, multiple parallel connected bond wires is not a solution.

This disclosure relates to approaches for detecting single point bond wire loss failures. The approaches described herein allow for compliance with safety functional standards (e.g., for automotive applications) for bond wire loss failure mechanisms. For instance, the approaches described herein allow for detection of bond wire losses during testing of an integrated circuit (e.g., prior to shipment to a customer and inclusion in a system implementing a safety function). This disclosure relates to implementations of safety mechanisms that provide for redundancy in the event of a single-point bond wire loss failure of an integrated circuit, e.g., during operation in the field. For instance, the disclosed approaches can detect and provide an indication of a bond wire loss. That indication can be accessible external to the corresponding integrated circuit, and can be used to initiate a safe operating state. In automotive applications, a safe operating state, depending on the particular safety function affected, can include providing an error indication, activating a redundant system or function, disabling one or more systems in a corresponding vehicle, etc. The particular details of a safe operating state will depend on the particular implementation (e.g., safety system)

While the approaches described herein are discussed with reference to automotive functional safety standards, the described techniques can be used in other applications, such as industrial applications, consumer electronics applications, etc. to provide for fault detection and/or to provide safety mechanisms. Further, while the approaches described herein are discussed with reference to detection of bond wire loss associated with ground supply pins for an integrated circuit, the disclosed techniques can be used to detect bond wire loss associated with other integrated circuit package pins, such as signal pins (e.g., input/output pins).

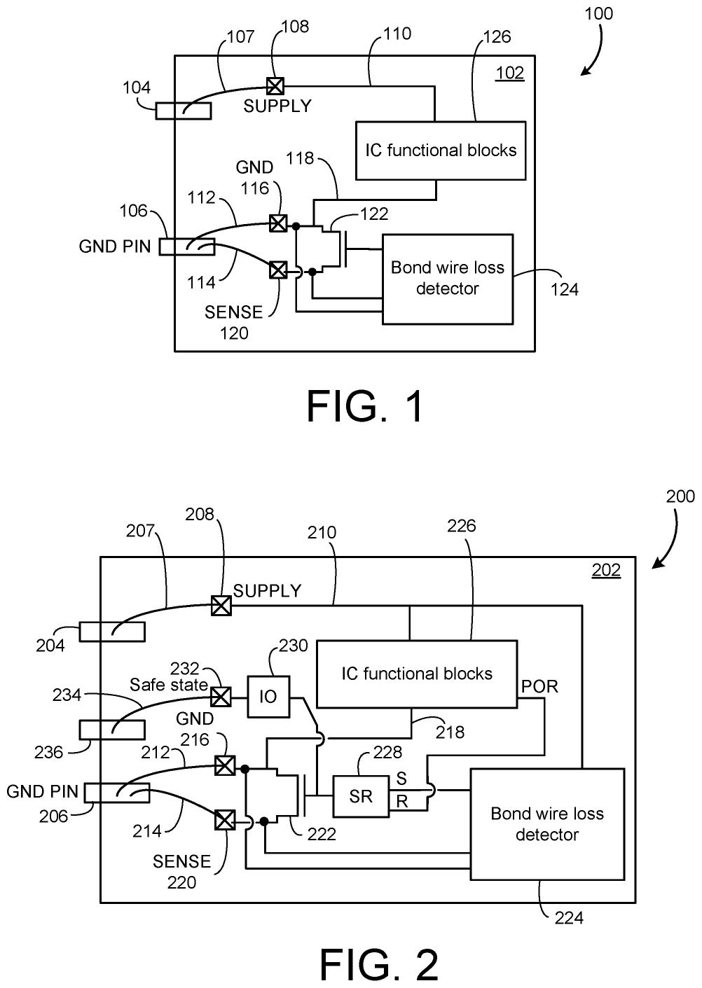

FIG. 1 is a block/schematic diagram illustrating a semiconductor device 100 that implements bond wire loss detection. As shown in FIG. 1, the semiconductor device 100 includes a package 102 having a plurality of pins (e.g., signal pins, power supply pins, test pins, etc.), including a pin 104 and a pin 106. The package 102 can be any number of semiconductor device package types, and can include additional pins, other than the illustrated pins. For instance, the semiconductor device 100 can include pins used for functional operation of an integrated circuit (IC) of the semiconductor device 100, pins for testing the IC, etc. In the example of FIG. 1, the semiconductor device 100 also includes a bond wire 107 that electrically couples (e.g., extends between) the pin 104 and a bond pad 108 of the IC, where the bond pad 108 is electrically coupled with a power supply bus 110 of the IC.

The semiconductor device 100 also includes a bond wire 112, and a bond wire 114. The bond wire 112 extends between (e.g., electrically couples) pin 106 and a bond pad 116, while the bond wire 114 extends between (e.g., electrically couples) pin 106 and a bond pad 120. In this example, the bond pad 116 is electrically coupled with a ground supply bus 118 of the IC, while the bond pad 120 is used to provide a sense signal for bond wire loss detection in the semiconductor device 100.

As shown in FIG. 1, the semiconductor device 100 (e.g., the IC) also includes a pass transistor 122 and a bond wire loss detection circuit 124. The bond pad 116 and the bond pad 120 are also operationally coupled with the bond wire loss detection circuit 124 to allow for bond wire loss detection (e.g., for loss of the bond wire 112 of loss of the bond wire 114). The semiconductor device 100 also includes one or more IC functional blocks 126, where the one or more IC functional blocks 126 can implement an ignition controller, a brake controller, or an airbag controller, as some examples.

In example implementations, the bond wire loss detection circuit 124 can be configured to detect a voltage difference between a voltage on the bond pad 116 and a voltage on the bond pad 120, where a voltage difference that is greater than a threshold voltage (e.g., ±350 millivolts) can indicate lack, or loss of electrical continuity between the pin 106 and the bond pad 116, or lack, or loss of electrical continuity between the pin 106 and the bond pad 120 (e.g., bond wire loss or failure).

In the semiconductor device 100, the pass transistor 122 and the bond wire loss detection circuit 124 act as a feedback system. In this example, the pass transistor 122 can be an n-channel metal-oxide-semiconductor (NMOS) transistor, with its source terminal electrically coupled with the bond pad 120 and its drain terminal electrically coupled with the bond pad 116. In other implementations, other transistors, devices or gates can be used as a pass device.

In the example of FIG. 1, in response to the bond wire loss detection circuit 124 detecting a voltage difference between the bond pad 116 and the bond pad 120 that is above an associated threshold voltage, indicating loss one of the bond wire 112 or the bond wire 114, the bond wire loss detection circuit 124 can, in response to this detection, be configured to activate the pass transistor 122. Activation of the pass transistor 122 provides a conductive path between the bond pad 116 and the bond pad 120. For instance, the pass transistor 122 can be activate by the bond wire loss detection circuit 124 for providing a logic high (logic 1) signal to a gate terminal of the pass transistor 122.

Such an approach provides a redundant safety mechanism for providing an electrical ground reference for operation of the IC of the semiconductor device 100. For instance, if the bond wire 112 were to fail, the one or more IC functional blocks 126 would become inoperable, as they would no longer have an electrical ground supply reference provided on the ground supply bus 118. The redundant mechanism the bond wire loss detection circuit 124 activating the pass transistor 122 allows for the IC of the semiconductor device 100 to remain functional in the event of loss of the bond wire 112 (of loss of the bond wire 114).

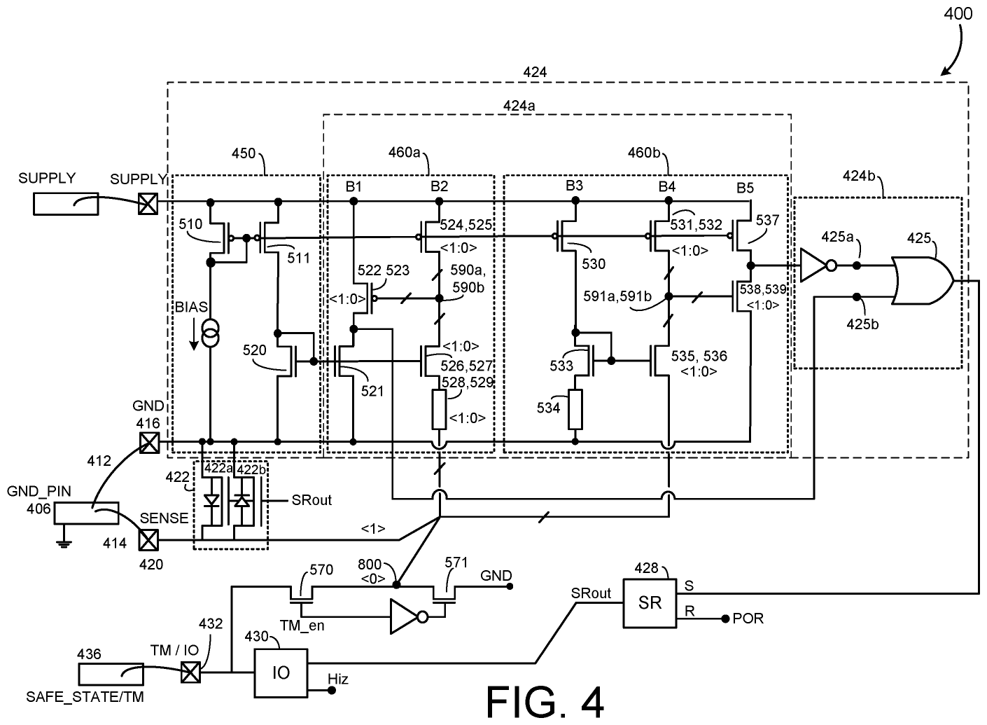

In some implementations, the bond wire loss detection circuit 124 can include test circuitry that allows operating the bond wire loss detection circuit 124 to confirm its proper operation. For instance, in an example implementation, the bond wire loss detection circuit 124 can include an additional input terminal, which, in a test mode, could be connected to a test pin of the IC and the test pin connected to an external voltage source. The voltage source could then be swept (e.g., from −400 mV to +400 mV) such that a positive threshold and a negative threshold of the bond wire loss detector can be measured. In a normal operation mode of the IC, this additional input terminal would not be used (e.g., could be connected, via a transistor, to one of the two functional inputs). An example of such an approach is further illustrated in FIG. 4.

FIG. 2 is a block diagram illustrating another semiconductor device 200 that implements bond wire loss detection. In this example, elements of the semiconductor device 200 that correspond with (e.g., are similar to) elements of the semiconductor device 100 are referenced with like 200 series reference numbers as the corresponding element's 100 series reference numbers in FIG. 1. For instance, the semiconductor device 200 includes a package 202, a pin 204, a pin 206, a bond wire 207, a bond pad 208, a power supply bus 210, a bond wire 212, a bond wire 214, a bond pad 216, a ground supply bus 218, a bond pad 220, a pass transistor 222, a bond wire loss detection circuit 224, and one or more IC functional blocks 226. For purposes of brevity, similar aspects of these elements described above are not described in detail again with reference to the semiconductor device 200 of FIG. 2.

As shown in FIG. 2, the semiconductor device 200, as compared to the semiconductor device 100, further includes a set-reset latch 228, an input/output circuit (I/O 230), a bond pad 232, a bond wire 234 and a pin 236. The set-reset latch 228, which could be implemented using a different type of latch circuit, is operationally coupled between the one or more IC functional blocks 226 and the gate terminal of the pass transistor 222. In this example, the one or more IC functional blocks 226 can implement a power-on reset (POR), which releases (e.g., from logic 1 to logic 0) a reset (R) signal or terminal of the set-reset latch 228 when the semiconductor device 200 is first powered on. Such a POR reset function can be implemented, for example, using a comparator that senses that supply voltage of the IC has increased from below a supply voltage threshold to above the supply voltage threshold. The POR reset function can be configured to place the IC in a known state, e.g., to ensure operation of the IC, though other approaches are possible.

The set-reset latch 228, when reset, deactivates the pass transistor 222 (e.g., places the pass transistor 222 in a non-conductive state). If the bond wire 212 and the bond wire 214 are intact and properly connected in the semiconductor device 200, the bond wire loss detection circuit 224 will not detect a voltage difference between the bond pad 216 and the bond pad 220, the set-reset latch 228 will remain unset (e.g., ready to be SET), and the pass transistor 222 will remain deactivated.

Additionally, in example implementations, the set-reset latch 228 of the semiconductor device 200 can prevent oscillation of its bond wire loss detection feedback loop. In other implementations, such as the example, of FIG. 1, a similar latching circuit or function can be integrated in a bond wire loss detector, such as the bond wire loss detection circuit 124. For instance, referring again to FIG. 1, without such a latching function, if a loss of the bond wire 112 or loss of the bond wire 114 is detected, the bond wire loss detection circuit 124 would indicate that loss (in response to detecting a voltage difference, as described above) and activate the pass transistor 122. However, depending on the detection threshold of the bond wire loss detection circuit 124 and a drain-to-source voltage of the activated pass transistor 122, the bond wire loss detection circuit 124 could deactivate the pass transistor 122 (e.g., if the active drain-to-source voltage is lower than the threshold voltage), until a voltage differential associated with the bond wire loss (e.g., above the bond wire loss detection circuit 124's threshold) is again detected, and the pass transistor 122 is again activated. This interaction could repeat and, as a result, can cause the pass transistor 122 to oscillate between its active state and its inactive state. Such oscillation could, in turn, affect proper function of the one or more IC functional blocks 126 of the semiconductor device 100 due to repeated loss of electrical ground. Use a latching function that is integrated in a bond wire loss detection circuit, or implemented separately from a bond wire loss detection circuit, such the set-reset latch 228 of FIG. 2, prevents such oscillation.

Referring again to FIG. 2, in this example, the I/O 230 is coupled (e.g., electrically coupled, operationally coupled, etc.) between the output of the set-reset latch 228 and the bond pad 232. Accordingly, an indication of bond wire loss detection that is latched in the set-reset latch 228 can be provided on the pin 236 (via the I/O 230, the bond pad 232, and the bond wire 234). Accordingly, the indication of bond wire loss in the semiconductor device 200 can be accessible external to the semiconductor device 200. Such an indication, e.g., on the pin 236, can be used by a module or other system that includes the semiconductor device 200 to initiate a safe operation state, as appropriate for the particular implementation. In some implementations, a bond wire loss indication can be accessed external to a corresponding semiconductor device in other ways, such as by using a diagnostic, and/or scan chain interface. Further, in example implementations, the bond wire loss detection circuit 224 can be configured to allow for testing of the bond wire loss detection functionality of the semiconductor device 200, such as described above with respect to the bond wire loss detection circuit 124 of the semiconductor device 100.

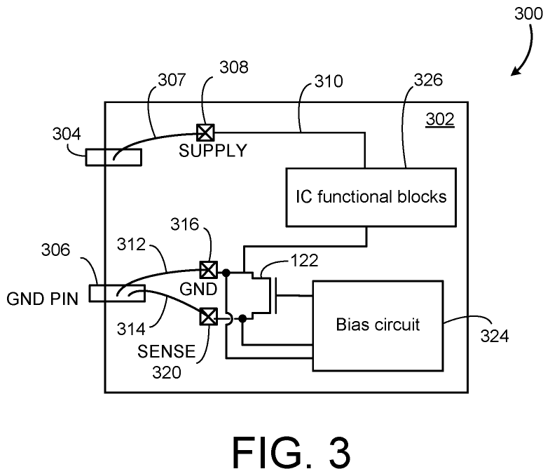

FIG. 3 is a is a block/schematic diagram illustrating another semiconductor device 300 that implements bond wire loss detection. In this example, elements of the semiconductor device 300 that correspond with (e.g., are similar to) elements of the semiconductor device 100 are referenced with like 200 series reference numbers as the corresponding element's 100 series reference numbers in FIG. 1. For instance, the semiconductor device 300 includes a package 302, a pin 304, a pin 306, a bond wire 307, a bond pad 308, a power supply bus 310, a bond wire 312, a bond wire 314, a bond pad 316, a ground supply bus 318, a bond pad 320, a pass transistor 322, and one or more IC functional blocks 326. For purposes of brevity, similar aspects of these elements described above are not described in detail again with reference to the semiconductor device 300 of FIG. 3.

As shown in FIG. 3, the semiconductor device 300, as compared to the semiconductor device 100, includes a bias circuit 324 in place of the bond wire loss detection circuit 124. In this example, the pass transistor 322, during normal operation of the semiconductor device 300, can be normally on, or active. For instance, in some implementations, the pass transistor 322 can be a native NMOS transistor (e.g., with a zero voltage gate-to-source threshold voltage. Further in this example, the bias circuit 324, can be configured, in normal operation mode, to couple the gate terminal of the pass transistor 322 with its source terminal. Also, the bias circuit 324 can be configured, when operating in a test mode, to inactivate the pass transistor 322 (e.g., apply negative voltage to the gate terminal), to allow for testing proper connection of the bond wire 312 and the bond wire 314. If a voltage shift (e.g., from electrical ground) is detected, this indicates loss of one of bond wires. Such an approach could be used for time zero bond wire integrity testing of the semiconductor device 300.

FIG. 4 is a block/schematic diagram illustrating a bond wire loss feedback circuit 400 that implements bond wire loss detection. In some implementations, the bond wire loss feedback circuit 400 could be implemented, for example, in the semiconductor device 200 shown in FIG. 2. As FIG. 4 is provided as an example illustration of a bond wire loss feedback circuit, for purposes of brevity and clarity, other elements of a corresponding semiconductor device, such as some elements of the semiconductor device 200, are not shown in FIG. 4.

However, in this example, elements of the bond wire loss feedback circuit 400 shown in FIG. 4 that correspond with (e.g., are similar to) elements of the semiconductor device 200 are referenced with like 400 series reference numbers as their corresponding element's 200 series reference numbers in FIG. 2. For instance, the bond wire loss feedback circuit 400 includes a pin 406, a bond wire 412, a bond wire 414, a bond pad 416, a bond pad 420, a pass transistor 422, a bond wire loss detection circuit 424, and a set-reset latch 428. For purposes of brevity, similar aspects of these elements described above are not described in detail again with reference to the bond wire loss feedback circuit 400 of FIG. 4.

In some implementations of the bond wire loss feedback circuit 400, anti-parallel diodes can be coupled between the bond pad 416 and the bond pad 420, where the anti-parallel diodes can be configured to limit voltage excursions on the bond pad 416 and/or the bond pad 420 when the bond wire 412 and/or the bond wire 414 is disconnected (lost) before the pass transistor 422 is activated. In some implementations, such anti-parallel diodes can be implemented by electrostatic discharge protection diodes (not depicted in FIG. 4) or, as shown in FIG. 4, by splitting the pass transistor 422 into two transistors (e.g., an NMOS transistor 422a and an NMOS transistor 422b). As shown in FIG. 4, a drain terminal of the NMOS transistor 422a is connected to the source terminal of the 422b, while a source terminal of the NMOS transistor 422a is connected to a drain terminal of the NMOS transistor 422b to implement the anti-parallel diodes with body diodes of the transistors 422a and 422b.

As shown in FIG. 4, the bond wire loss detection circuit 424 includes a detection portion 424a and an indication portion 424b. In this example, the detection portion 424a includes a bond wire loss detector 460a that detects when bond wire 412 is disconnected. That is, the bond wire loss detector 460a detects when the voltage on bond pad 416, referenced to the bond pad 420, goes above a voltage threshold (e.g., as defined by a voltage drop across resistor 528 or resistor 529. The detection portion 424a also include a bond wire loss detector 460b that detects when the bond wire 414 is disconnected. That is, the bond wire loss detector 460b detects when the voltage on bond pad 420 referenced to the bond pad 416 goes above a voltage threshold (e.g., as defined by a voltage drop across resistor 534).

In the example of FIG. 4, a bias reference 450 provides, via a diode-connected PMOS transistor 510, a voltage to the bond wire loss detection circuit 424. As shown in FIG. 4, the bond wire loss detector 460a includes branches B1 and B2, while the bond wire loss detector 460b includes branches B3, B4 and B5. As indicated in the schematic of FIG. 4, some of the elements of the branches B1, B2, B3 and B5 include multiple, parallel implemented elements, nodes and circuit paths, e.g., indexed as <0:1>. In this example, the <1> indexed elements can be used when a corresponding IC is operating in a normal operation mode, while the <0> indexed elements can be used while a corresponding IC is operating in a test mode. Accordingly, for purposes of brevity and illustration, the following discussion of the operation of the bond wire loss feedback circuit 400 makes reference to elements in both of these parallel paths. For instance, in the normal operation mode of the bond wire loss feedback circuit 400, a PMOS transistor 522 of the branch B1, a PMOS transistor 524 of the branch B2, an NMOS transistor 526 of the branch B2, a resistor 528 of the branch B2, a PMOS transistor 531 of the branch B4, an NMOS transistor 535 of the branch B4, and an NMOS transistor 538 of the branch B5 (the <1> indexed elements) can be used for operation of the bond wire loss detection circuit 424. In comparison, in the test mode of the bond wire loss feedback circuit 400, a PMOS transistor 523 of the branch B1, a PMOS transistor 525 of the branch B2, an NMOS transistor 527 of the branch B2, a resistor 529 of the branch B2, a PMOS transistor 532 of the branch B4, an NMOS transistor 536 of the branch B4, and an NMOS transistor 539 of the branch B5 (the <0> indexed elements) can be used for testing operation of the bond wire loss detection circuit 424. Further, a node 590a and a node 591a can be used in the normal operation mode, while a node 590b and a node 591b can be used in the test mode.

In the bond wire loss feedback circuit 400 of the FIG. 4, the voltage provided by the bias reference 450 is provided, as a same voltage to a PMOS transistor 511, a PMOS transistor 524, a PMOS transistor 525, a PMOS transistor 530, a PMOS transistor 531, a PMOS transistor 532, and a PMOS transistor 537, which, in this example, can all have a same current mirror ratio. Accordingly, in this arrangement, same value currents are provided, respectively, to a diode-connected NMOS transistor 520 and a diode-connected NMOS transistor 533, which in turn supplies same gate-to-source voltages to a NMOS transistor 521 and an NMOS transistor 533.

As indicated above, in normal operation mode of the bond wire loss feedback circuit 400, the detector 460a operates with the branch B2 including the PMOS transistor 524, the node 590a, the NMOS transistor 526, and the resistor 528, while in the test mode of the bond wire loss feedback circuit 400, the detector 460a operates with the branch B2 including the PMOS transistor 525, the node 590b, the NMOS transistor 527, and the resistor 529, and the resistor 529. As shown in FIG. 4, in the normal operation mode, the node 590a connects (electrically couples) a gate terminal of the PMOS transistor 522, a drain of terminal of the PMOS transistor 524, and a drain terminal of the NMOS transistor 526, while in the test mode, the node 590b connects (electrically couples) a gate terminal of the PMOS transistor 523, a drain terminal of the PMOS transistor 525, and a drain terminal of the NMOS transistor 527. Further, as indicated by the <1> index, in the normal operation mode, the branches B2 and B4 are connected to the bond pad 420 via the resistor 528 and the NMOS transistor 535, respectively. Still further, as indicated by the <0> index, in the test mode, the branches B2 and B4 are connected to a node 800 (a test mode node) via the resistor 529 and the NMOS transistor 536, respectively. In this example, the node 800 can be accessible from an IC including the bond wire loss feedback circuit 400, e.g., when the IC is configured to operation in a test mode. For instance, the node 800 can be used to emulate a bond wire loss by sweeping a voltage (e.g., from −550 millivolts to +550 millivolts) that is applied on the node 800.

In the bond wire loss feedback circuit 400, when the bond wire 412 and the bond wire 414 are connected as intended (e.g., providing electrical continuity from their respective bond pads to the pin 406), respective voltage potentials on the bond pad 416 and the bond pad 420 will be the same (approximately the same, nearly the same). In this situation, a gate-to-source voltage of a NMOS transistor 521 will be equal to a sum of a gate-to-source voltage of the NMOS transistor 526 and a voltage across the resistor 528 (and also equal to a sum of a gate-source voltage of the NMOS transistor 527 and a voltage across the resistor 529 for test mode). In other words, the gate-to-source voltage of the NMOS transistor 521 will be larger than a gate-to-source voltage of the NMOS transistor 526 and the 527, which will cause respective currents in the NMOS transistor 526 and the NMOS transistor 527 to be smaller than a current it the NMOS transistor 521. Since currents in the PMOS transistor 524 and the PMOS transistor 525 are approximately the same as a current in the NMOS transistor 521, a voltage on the node 590a (normal operation) or the node 590b (test mode) will be pulled towards the supply voltage, which will deactivate the 522 (normal operation) or the PMOS transistor 523, which will result in node 425b being grounded.

If, however, electrical continuity between, e.g., the bond wire 412 and the bond pad 416 is lost, or not present, a voltage on the bond pad 416 will increase, which will cause a gate voltage of the NMOS transistor 526 (normal operation) of the NMOS transistor 527 (test mode) to increase. Once the gate-to-source voltage of the NMOS transistor 526 (in normal operation), or the gate-to-source voltage of the NMOS transistor 527 becomes larger than a gate-to-source voltage of the 521, that increase voltage will provide more current than the PMOS transistor 524 (normal operation), or the PMOS transistor 525, such that the node 590a (normal operation), or the node 590b (test mode) will be pulled to ground and a resulting voltage on the node 425b will cause OR gate 425 to set the set-reset latch 428. The bond wire loss detector 460b, in response to loss of the bond wire 414, will operate similarly to the bond wire loss detector 460a, in response to loss of the bond wire 412. Accordingly, for purposes of brevity, details of operation of the bond wire loss detector 460b are not described here.

In the bond wire loss feedback circuit 400, when a TM_en control signal (indicated in FIG. 4) is disabled (e.g. pulled low), this places the bond wire loss feedback circuit 400 in its normal operation, and the node 800 is connected to (electrically coupled with) the bond pad 416 via NMOS transistor 571. However, when TM_en is enabled (e.g., pulled hi) NMOS transistor 570 will conduct and connect (electrically couple) node 800 to bond pad 432. In this example, the bond pad 432 is shared with IO 430, which can be used to indicate a bond wire loss and an inform a corresponding IC and/or system that a safe operating state should be entered. When the TM_en signal is enabled, the IO 430 is put in a high-impedance operating state by signal a HiZ, to prevent the IO 430 from interfering with with the test mode operation.

When the bond wire loss feedback circuit 400 is put in its test mode (e.g., TM_en and HiZ pulled high), an external test voltage can be sourced on pin 436. This test voltage can be swept, as noted above, from −550 mV to +550 mV to determine the threshold voltages of the bond wire loss detector 460a and the bond wire loss detector 460b, and to confirm proper operation of the bond wire loss detector 424.

The indication portion 424b of the bond wire loss detection circuit 424 includes the OR gate 425 that receives inputs that respectively indicated detection of a positive voltage differential with a magnitude greater than a threshold voltage (input 425a) on bond pad 420 (normal operation) or node 800 (test mode) referenced to bond pad 416, and detection of a negative voltage differential with a magnitude greater than the threshold voltage (input 425b). If either of such voltage differentials is detected, the OR gate 425 will output a logic one (logic high), setting the set-reset latch 428 and activating the pass transistor 422. As further shown in

FIG. 4, a supply voltage (e.g., an IC internal voltage) can be used to power the bond wire loss detection circuit 424. As with the semiconductor device 200, a POR function can be used to reset the set-reset latch 428, e.g., when an associated IC including the bond wire loss feedback circuit 400 is first powered or, when a supply voltage increases from below a supply threshold to above the supply threshold.

The various apparatus and techniques described herein may be implemented using various semiconductor processing and/or packaging techniques. Some embodiments may be implemented using various types of semiconductor processing techniques associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. A semiconductor device comprising:
a package including a plurality of pins;
a semiconductor die including:
a first bond pad;
a second bond pad; and
a pass transistor having:
a drain terminal electrically coupled with the first bond pad; and
a source terminal electrically coupled with the second bond pad;
a first bond wire extending between a pin of the plurality of pins and the first bond pad; and
a second bond wire extending between the pin and the second bond pad,
the pass transistor being configured to facilitate detection of at least one of:
lack of electrical continuity between the pin and the first bond pad, or
lack of electrical continuity between the pin and the second bond pad.

2. The semiconductor device of claim 1, wherein:
detecting the lack of electrical continuity between the pin and the first bond pad includes detecting a positive voltage shift between the first bond pad and the second bond pad; and
detecting the lack of electrical continuity between the pin and the second bond pad includes detecting a negative voltage shift between the first bond pad and the second bond pad.

3. The semiconductor device of claim 1, wherein the semiconductor die further includes a bond wire loss detection circuit operationally coupled with the first bond pad and operationally coupled with the second bond pad,
the bond wire loss detection circuit being configured to detect a voltage differential between the first bond pad and the second bond pad.

4. The semiconductor device of claim 3, wherein:
the bond wire loss detection circuit is further operationally coupled with a gate terminal of the pass transistor; and
the bond wire loss detection circuit is further configured, in response to the detected voltage differential exceeding a threshold, to activate the pass transistor, such that the pass transistor provides a conductive path between the first bond pad and the second bond pad.

5. The semiconductor device of claim 3, wherein the semiconductor die further includes a latch operationally coupled between the bond wire loss detection circuit and a gate terminal of the pass transistor,
the bond wire loss detection circuit being further configured, in response to the detected voltage differential exceeding a threshold, to set the latch, and
the latch being configured, when set, to activate the pass transistor, such that the pass transistor provides a conductive path between the first bond pad and the second bond pad.

6. The semiconductor device of claim 5, wherein:
the latch is a set-reset latch, the set-reset latch being configured, when reset, to deactivate the pass transistor.

7. The semiconductor device of claim 6, further comprising at least one functional block configured to release a reset signal of the set-reset latch in response to a supply voltage of the semiconductor device increasing from below a supply voltage threshold to above the supply voltage threshold.

8. The semiconductor device of claim 5, wherein an output signal of the latch is accessible external to the semiconductor device.

9. The semiconductor device of claim 1, wherein the pass transistor is an n-channel metal-oxide-semiconductor (NMOS) transistor.

10. The semiconductor device of claim 9, wherein the NMOS transistor is a native NMOS transistor.

11. The semiconductor device of claim 1, wherein the pin is an electrical ground supply pin of the semiconductor device.

12. An integrated circuit comprising:
a first bond pad coupled with a ground supply bus for the integrated circuit;
a pass transistor having a drain terminal, a source terminal and a gate terminal, the drain terminal being electrically coupled with the first bond pad;
a second bond pad electrically coupled with the source terminal;
a detection circuit operationally coupled with the first bond pad and the second bond pad, the detection circuit being configured to provide an indication signal in response to a voltage differential between a voltage on the first bond pad and a voltage on the second bond pad exceeding a threshold; and
a set-reset latch configured to set an output signal in response to receiving the indication signal,
the gate terminal being configured to:
receive the output signal, and
activate the pass transistor in response to the output signal being set, such that the pass transistor provides a conductive path between the first bond pad and the second bond pad.

13. The integrated circuit of claim 12, further comprising at least one functional block configured to release a reset signal of the set-reset latch in response to a supply voltage of the semiconductor device increasing from below a supply voltage threshold to above the supply voltage threshold.

14. The integrated circuit of claim 12, wherein an output signal of the set-reset latch is accessible external to the integrated circuit.

15. The integrated circuit of claim 12, wherein the pass transistor is an n-channel metal-oxide-semiconductor (NMOS) transistor.

16. An integrated circuit comprising:
a first bond pad electrically coupled with a ground supply bus for the integrated circuit;
a pass transistor having a drain terminal, a source terminal and a gate terminal, the drain terminal being electrically coupled with the first bond pad;
a second bond pad electrically coupled with the source terminal; and
a bias circuit operationally coupled with the gate terminal, the bias circuit being configured to:
in a normal operation mode of the integrated circuit, activate the pass transistor, and
in a test mode of the integrated, deactivate the pass transistor.

17. The integrated circuit of claim 16, wherein the pass transistor is an n-channel metal-oxide-semiconductor (NMOS) transistor.

18. The integrated circuit of claim 17, wherein the NMOS transistor is a native NMOS transistor.

19. The integrated circuit of claim 18, wherein deactivating the pass transistor includes applying a negative voltage to the gate terminal.
